(19) United States
(12) Patent Application Publication
(10) Pub. No.: US 2026/0060046 A1
(43) Pub. Date: Feb. 26, 2026

(54) METHOD OF MANUFACTURING A SEMICONDUCTOR DEVICE USING A CARBON MASK PATTERN

(71) Applicant: SK hynix Inc., Gyeonggi-do (KR)

(72) Inventors: Sang Hyu SHIN, Gyeonggi-do (KR); Jae Chun CHA, Gyeonggi-do (KR); Bong Seok JEON, Gyeonggi-do (KR)

(21) Appl. No.: 19/055,533

(22) Filed: Feb. 18, 2025

(30) Foreign Application Priority Data
Aug. 23, 2024 (KR) 10-2024-0113527

(51) Int. Cl. H01L 21/033; H01L 21/308; H01L 21/311; H01L 21/3213; H01L 21/768; H10D 64/01

(52) U.S. Cl. CPC H01L 21/0337; H01L 21/3081; H01L 21/31144; H01L 21/32139; H01L 21/768; H10D 64/01

(57) ABSTRACT

A method of manufacturing a semiconductor device including forming a target layer, forming a pre-modification carbon layer over the target layer, modifying and patterning the pre-modification carbon layer to form a post-modification carbon mask pattern by performing a modification process and a patterning process, and forming trenches in the target layer by performing an etching process using the post-modification carbon mask pattern as an etching mask.

### CROSS-REFERENCE TO RELATED APPLICATIONS

This patent document claims priority under 35 U.S.C. 119(a) to Korean Patent Application No. 10-2024-0113527, filed on Aug. 23, 2024, which is incorporated herein by reference in its entirety.

### TECHNICAL FIELD

Embodiments of the present disclosure relate generally to semiconductor technology and more in particular to a method of forming a post-modification carbon mask pattern by modifying a carbon layer and to a method of manufacturing a semiconductor device using the carbon mask pattern.

### BACKGROUND

As the size of the various elements of a semiconductor device, such as, for example, the length of a transistor decreases to less than nanoscale, the patterning technology becomes more important. Patterning involves creating specific patterns on a semiconductor wafer to define the various components of a semiconductor device.

One important aspect of the patterning technology is the use of an etch mask. An etch mask is a material layer that protects certain areas of wafer during etching, which removes material from unprotected areas to create a desired pattern. Accordingly, in the patterning technology, as devices become smaller, a need for an improved etch mask with better etching resistance has emerged.

### SUMMARY

An embodiment of the present disclosure provides a method of replacing some of sp2 hybrid carbon bonding structures in a carbon layer with sp3 hybrid carbon bonding structures.

An embodiment of the present disclosure provides a method of modifying a nanocrystalline carbon layer into an amorphous carbon layer.

An embodiment of the present disclosure provides a method of using a nanocrystalline carbon layer as a mask pattern in a patterning process for forming a semiconductor device by modifying a nanocrystalline carbon layer into an amorphous carbon layer.

In accordance with an embodiment of the present disclosure, a method of manufacturing a semiconductor device includes forming a target layer, forming a pre-modification carbon layer over the target layer, modifying and patterning the pre-modification carbon layer to form a post-modification carbon mask pattern by performing a modification process and a patterning process, and forming trenches in the target layer by performing an etching process using the post-modification carbon mask pattern as an etching mask.

In accordance with an embodiment of the present disclosure, a method of manufacturing a semiconductor device includes forming a target layer, forming a pre-modification carbon layer over the target layer, patterning the pre-modification carbon layer to form a post-modification carbon mask pattern, modifying the pre-modification carbon mask pattern to form a post-modification carbon mask pattern by performing an ion implantation process, forming trenches in the target layer by performing an etching process using the post-modification carbon mask pattern as an etching mask, and forming trench patterns in the trenches. Each of the pre-modification carbon mask patterns and the post-modification carbon mask pattern includes sp2 hybrid carbon bonding structures and sp3 hybrid carbon bonding structures. A number of the sp3 hybrid carbon bonding structures in the pre-modification carbon mask pattern is less than a number of the sp3 hybrid carbon bonding structures in the post-modification carbon mask pattern.

In accordance with an embodiment of the present disclosure, a method of manufacturing a semiconductor device includes forming a pre-modification carbon layer over a target layer, and modifying the pre-modification carbon layer to form a post-modification carbon layer by performing an ion implantation process. Each of the pre-modification carbon layer and the post-modification carbon layer includes sp2 hybrid carbon bonding structures and sp3 hybrid carbon bonding structures. A number of the sp2 hybrid carbon bonding structures in the pre-modification carbon layer is greater than a number of the sp2 hybrid carbon bonding structures in the post-modification carbon layer. A number of the sp3 hybrid carbon bonding structures in the pre-modification carbon layer is less than a number of the sp3 hybrid carbon bonding structures in the post-modification carbon layer.

These and other features and advantages of the embodiments of the present disclosure will become apparent to those skilled in the art from the following detailed description in conjunction with the following drawings.

### BRIEF DESCRIPTION OF THE DRAWINGS

FIGS. 1A and 1B are views illustrating a method of modifying a carbon layer according to an embodiment of the present disclosure.

FIGS. 2A to 2F are longitudinal cross-sectional views schematically illustrating a method of manufacturing a semiconductor device according to an embodiment of the present disclosure.

FIGS. 3A to 3D are views illustrating a method of manufacturing a semiconductor device according to an embodiment of the present disclosure.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

In a semiconductor manufacturing process technology, it has been proposed to use a diamond-like carbon layer as a material layer for mask patterns with excellent etching resistance. Because the diamond-like carbon layer includes enough sp3 hybrid carbon bonding structures, the diamond-like carbon layer has excellent etching resistance. However, the diamond-like carbon layer has very high stress because upper and lower carbon layers are bonded to each other because of vertical bonding structures of the sp3 hybrid carbon bonding structures. As a result, a warpage of a wafer is severely distorted due to the stress, and an edge of a pattern is not uniform and a wave shaped wiggling occurs. This phenomenon is particularly severe near the edge of the wafer, and defects such as a short-circuiting or a bridge of patterns may occur.

The embodiments of the present disclosure provide an elegant solution to the aforementioned problems. The embodiments suppress distortion and wiggling caused by the stress by forming a nano-crystalline graphite carbon layer containing fewer vertical bonding structures. They may also modify the nano-crystalline graphite carbon layer into an amorphous carbon layer through a modifying process that enables the use of the amorphous carbon layer as a hard mask pattern. Moreover, a method for improving etching resistance by replacing the horizontal bonding structures with vertical bonding structures is disclosed.

In the present disclosure, a sum of the sp2 hybrid carbon bonding structures and the sp3 hybrid carbon bonding structures in a pre-modification carbon layer 51 is 100%.

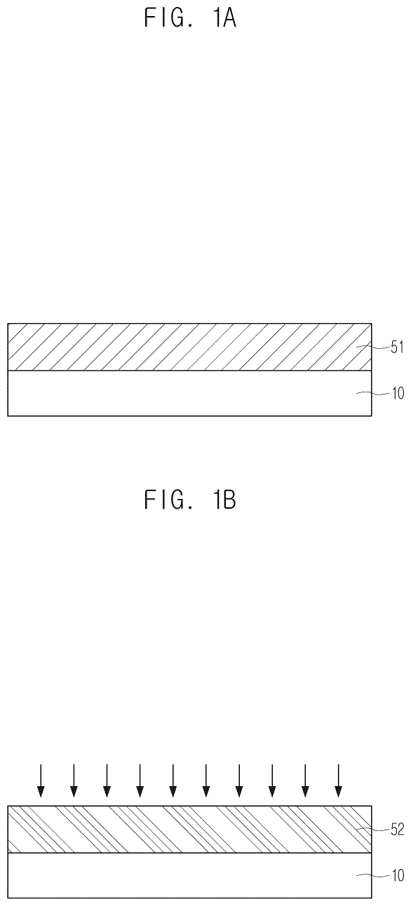

FIGS. 1A and 1B are views illustrating a method of modifying a carbon layer according to an embodiment of the present disclosure. Referring to FIG. 1A, the method of modifying the carbon layer may include forming a pre-modification carbon layer 51 on an underlying layer 10 by performing a high-temperature deposition process. The underlying layer 10 may include at least one of a silicon layer, a silicon oxide layer, a silicon nitride layer, a metal layer, a metal nitride layer, or a metal oxide layer. The high-temperature deposition process may be performed under a temperature condition of about 550° C. or more, for example, about 640° C. The pre-modification carbon layer 51 formed through the high-temperature deposition process may be a nano-crystalline graphite carbon layer. The nano-crystalline graphite carbon layer refers to a thin film composed of graphite crystals at the nanometer scale. The pre-modification carbon layer 51 may include a relatively high proportion of the sp2 hybrid carbon bonding structures and a relatively low proportion of the sp3 hybrid carbon bonding structures. In the pre-modification carbon layer 51, a number, amount, and ratio of the sp2 hybrid carbon bonding structures may be greater than or higher than a number, amount, and structure of the sp3 hybrid carbon bonding structures. In an embodiment, the pre-modification carbon layer 51 may include the sp2 hybrid carbon bonding structures in a range of about 50% to 100% and the sp3 carbon bonding structures in a range of 0% to 50%. In an embodiment, the pre-modification carbon layer 51 may include the sp2 hybrid carbon bonding structures in a range of 75% to 100% and the sp3 carbon bonding structures in a range of 0% to 25%. In an embodiment, the pre-modification carbon layer 51 may include the sp2 hybrid carbon bonding structures in a range of 80% to 100% and the sp3 hybrid carbon bonding structures in a range of 0% to 20%. That is, in the pre-modification carbon layer 51, the number of the sp2 hybrid carbon bonding structures may be greater than the number of the sp3 hybrid carbon bonding structures. The pre-modification carbon layer 51 has a low stress, because the pre-modification carbon layer 51 has a smaller number of the sp3 hybrid carbon bonding structures than a diamond-like carbon layer and an amorphous carbon layer. The diamond-like carbon layer and the amorphous carbon layer have a larger number of the sp3 hybrid carbon bonding structures than the pre-modification carbon layer 51. Thus, the pre-modification carbon layer 51 may exhibit improved characteristics such as lower distortion characteristics and wiggling characteristics.

Referring to FIG. 1B, the method may further include performing a modification process to modify the pre-modification carbon layer 51 of FIG. 1A into a post-modification carbon layer 52. The post-modification carbon layer 52 may be an amorphous carbon layer. By the modifying process, the sp2 hybrid carbon bonding structures may be reduced and the sp3 hybrid carbon bonding structures may be increased. For example, the post-modification carbon layer 52 may include the sp2 hybrid carbon bonding structures of 80% or less and the sp3 hybrid carbon bonding structures of 20% or more. In an embodiment, the post-modification carbon layer 52 may include the sp2 hybrid carbon bonding structures of 75% or less and the sp3 carbon bonding structures of 25% or more. In an embodiment, the post-modification carbon layer 52 may include the sp2 hybrid carbon bonding structures in a range of 40% to 70% and the sp3 hybrid carbon bonding structures in a range of 30% to 60%. In an embodiment, the post-modification carbon layer 52 may include relatively few sp2 hybrid carbon bonding structures and relatively many sp3 hybrid carbon bonding structures.

The modification process may include an ion implantation process. The ion implantation process may include implanting at least one of boron ions, boron compound ions such as boron fluoride ions, carbon ions, silicon compound ions, argon ions, xenon ions, phosphorus ions, arsenic ions, germanium ions, indium ions, or antimony ions into the pre-modification carbon layer 51. Process conditions of the ion implantation process may be adjusted according to a thickness of the pre-modification carbon layer 51 and a target ratio of the sp2 hybrid carbon bonding structures and the sp3 hybrid carbon bonding structures. For example, the ion implantation process may be performed under an energy condition of a range of 0.2 to 300 keV. By the ion implantation process, some of the sp2 hybrid carbon bonding structures may be replaced with the sp3 carbon bonding structures in the pre-modification carbon layer 51. For example, double covalent bond structures in the sp2 hybrid carbon bonding structures may be replaced with single covalent bond structures. That is, a number of the sp2 hybrid carbon bonding structures may decrease, and a number of the sp3 hybrid carbon bonding structures may increase. Therefore, the post-modification carbon layer 52 may have improved (i.e., enhanced) etching resistance compared to the pre-modification carbon layer 51.

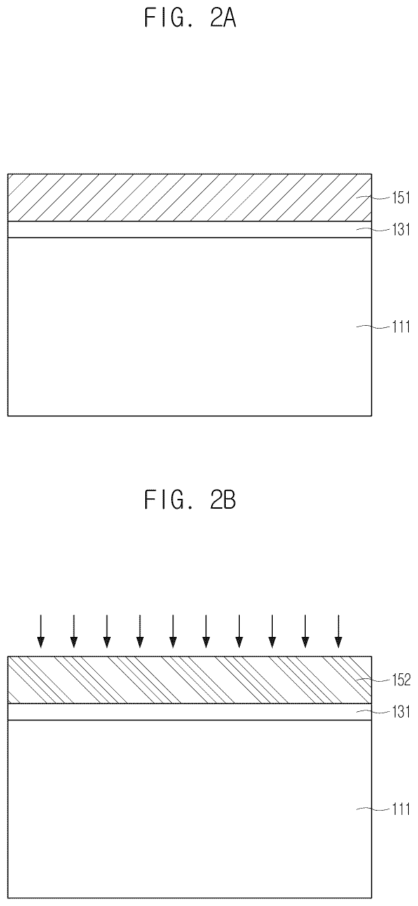

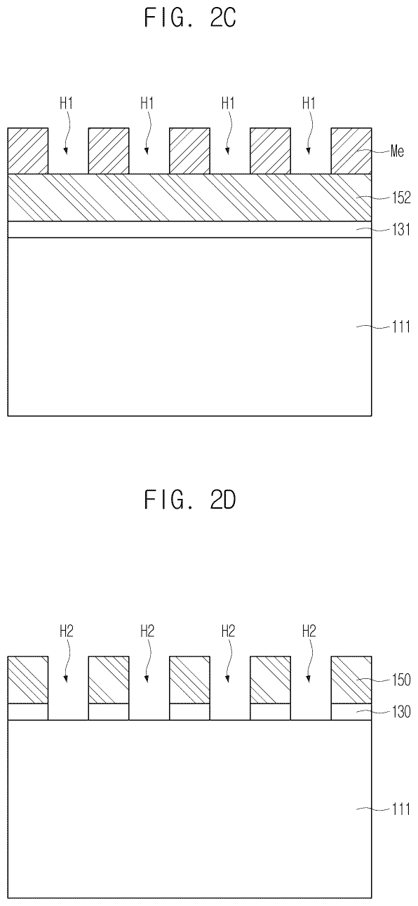

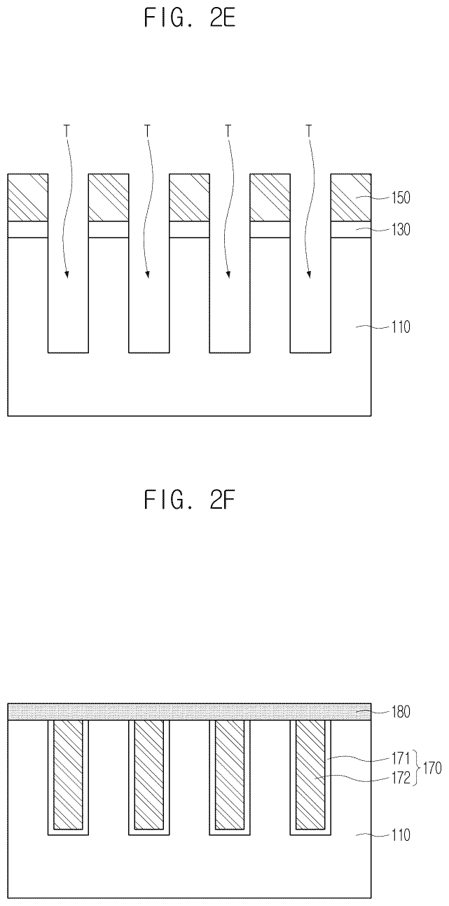

FIGS. 2A to 2F are longitudinal cross-sectional views schematically illustrating a method of manufacturing a semiconductor device according to an embodiment of the present disclosure. For example, there is provided a method of patterning an etching target layer using a post-modification carbon mask pattern by the inventive technical concepts of the present disclosure.

Referring to FIG. 2A, the method may include forming a buffer layer 131 on a target layer 111 and forming a pre-modification carbon layer 151 on the buffer layer 131.

The target layer 111 may be one of a silicon substrate, an interlayer insulating layer, a conductive pattern, or an insulating pattern. In an embodiment, the target layer 111 may include at least one of a silicon oxide layer, a metal layer, a metal compound layer, or a silicon nitride layer.

The buffer layer 131 may protect the target layer 111 in processes of processing the pre-modification carbon layer 151. For example, the buffer layer 131 may prevent damage to the target layer 111 due to an ion implantation process. The buffer layer 131 may block ion movement and/or ion diffusion between the pre-modification carbon layer 151 and the target layer 111. The buffer layer 131 may improve an adhesion between the target layer 111 and the pre-modification carbon layer 151. The buffer layer 131 may include at least one of inorganic layers such as a silicon oxide layer, a silicon nitride layer, a silicon carbide layer, or a polycrystalline silicon layer. In an embodiment, the buffer layer 131 may include stacked multiple material layers. In an embodiment, the buffer layer 131 may be omitted. In another embodiment, the buffer layer 131 may include a metal. For example, the buffer layer 131 may include a metal layer, a metal oxide layer, or a metal nitride layer.

The pre-modification carbon layer 151 may include a nano-crystalline graphite carbon layer. The pre-modification carbon layer 151 may be understood with reference to the pre-modification carbon layer 51 described in FIG. 1A.

Referring to FIG. 2B, the method may further include implanting ions into the pre-modification carbon layer 151 by performing an ion implantation process. The pre-modification carbon layer 151 may be modified to the post-modification carbon layer 152 by implanting the ions. The ion implantation process will be understood with reference to FIGS. 1A and 1B. The post-modification carbon layer 152 may be an amorphous carbon layer. The post-modification carbon layer 152 may be understood with reference to the post-modification carbon layer 52 in FIG. 1B.

Referring to FIG. 2C, the method may further include forming an etching mask pattern Me on the post-modification carbon layer 152 by performing a photolithography process. The etching mask pattern Me may include a photoresist. The etching mask pattern Me may include mask holes H1 selectively exposing surfaces of the post-modification carbon layer 152. The mask holes H1 may be arranged spaced apart from each other at a regular interval.

Referring to FIG. 2D, the method may further include performing a first etching process to selectively etch the post-modification carbon layer 152 and the buffer layer 131 of FIG. 2C to form a post-modification carbon mask pattern 150 and a buffer pattern 130. The post-modification carbon mask pattern 150 and the buffer pattern 130 may include etching holes H2 selectively exposing the target layer 111. The method may further include removing the etching mask pattern Me. In an embodiment, the buffer layer 131 of FIG. 2C may remain without being patterned. That is, the etching holes H2 may selectively expose surfaces of the buffer layer 131 of FIG. 2C. The etching holes H2 of the post-modification carbon mask pattern 150 may selectively expose surfaces of the buffer layer 131. In another embodiment, a portion of an upper portion of the buffer layer 131 of FIG. 2C may be partially etched. In another embodiment, when the buffer layer 131 of FIG. 2C includes multiple material layers, some material layers located at an upper portion of the buffer layer 131 may be etched, and some material layers located at a lower portion of the buffer layer 131 may remain.

Referring to FIG. 2E, the method may further include etching the target layer 111 to form trenches T by performing a second etching process. The target layer 111 may be formed to a target pattern 110 including the trenches T. Thereafter, the method may further include removing the post-modification carbon mask pattern 150 and the buffer pattern 130.

Referring to FIG. 2F, the method may further include forming trench patterns 170 in the trenches T. The method may further include forming a capping layer 180. Each of the trench patterns 170 may include a liner pattern 171 formed conformally on the sidewall and bottom surface of each of the trenches T. Each of the trench patterns 170 may also include a plug pattern 172 filling the remaining space of each of the trenches T. In an embodiment, the liner pattern 171 may include a gate dielectric layer, and the plug pattern 172 may include a gate electrode. For example, the liner pattern 171 may include at least one of a silicon oxide layer, a high-k dielectric layer, and a dipole material layer. The high-k dielectric layer may include at least one metal oxide layer such as a hafnium oxide layer, a zirconium oxide layer, or a hafnium zirconium oxide layer. The dipole material layer may include at least one of a lanthanum oxide layer, an aluminum oxide layer, or a lanthanum aluminum oxide layer. The plug pattern 172 may include at least one of doped polycrystalline silicon, a metal, a metal silicide, a metal nitride, or a metal alloy. In another embodiment, the liner pattern 171 may include a barrier material layer. For example, the liner pattern 171 may include a metal nitride such as titanium nitride, tantalum nitride, or tungsten nitride. The capping layer 180 may include a capping material layer or a barrier material layer. For example, the capping layer 180 may include a silicon nitride layer. In an embodiment, the capping layer 180 may include a metal compound layer such as a titanium nitride layer or a tungsten nitride layer. In another embodiment, the capping layer 180 may include at least one of a metal layer, a polycrystalline silicon layer, or a metal silicide layer.

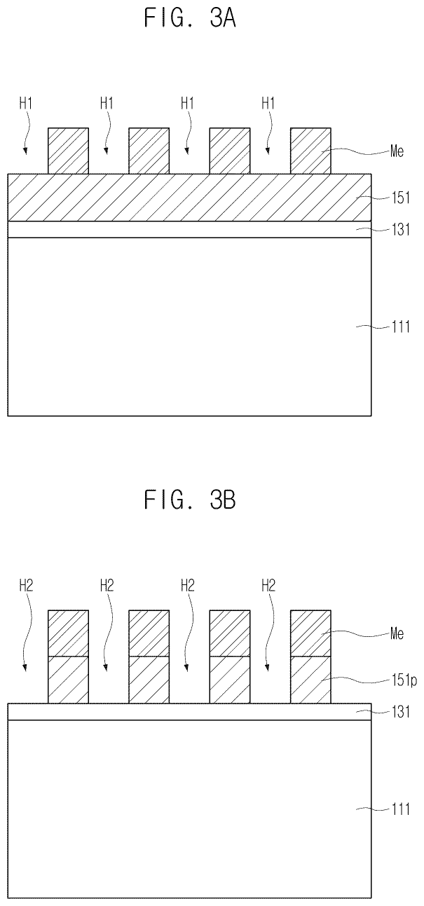

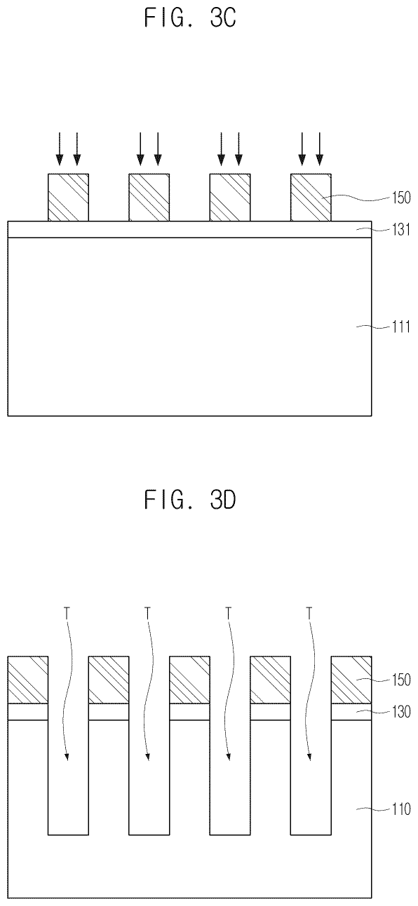

FIGS. 3A to 3D are views illustrating a method of manufacturing a semiconductor device according to an embodiment of the present disclosure. Referring to FIG. 3A, the method may include forming a buffer layer 131 on a target layer 111, forming a pre-modification carbon layer 151 on the buffer layer 131, and forming an etching mask pattern Me on the pre-modification carbon layer 151. The etching mask pattern Me may include mask holes H1 selectively exposing a surface of the pre-modification carbon layer 151. In an embodiment, the buffer layer 131 may be omitted. In another embodiment, the buffer layer 131 may include multiple material layers. The etching mask pattern Me may include a photoresist. In an embodiment, an additional buffer layer may be further formed between the pre-modification carbon layer 151 and the etching mask pattern Me. In an embodiment, the additional buffer layer may include multiple material layers. In an embodiment, the buffer layer 131 and the additional buffer layer may include the same material.

Referring to FIG. 3B, the method may further include selectively etching the pre-modification carbon layer 151 exposed in the mask holes H1 by performing a first etching process. The pre-modification carbon layer 151 may be patterned into a pre-modification carbon mask pattern 151p having etching holes H2 spaced apart from each other at a regular interval. The etching holes H2 may selectively expose the buffer layer 131.

Referring to FIG. 3C, the method may further include removing the etching mask pattern Me to expose the pre-modification carbon mask pattern 151p, and implanting ions into the exposed pre-modification carbon mask pattern 151p by performing an ion implantation process. The pre-modification carbon mask pattern 151p into which the ions are implanted may be modified into a post-modification carbon mask pattern 150.

Referring to FIG. 3D, the method may further include patterning the buffer layer 131 to form trenches T in the target layer 111 by performing an etching process using the post-modification carbon mask pattern 150 as an etching mask. The target layer 111 may be formed into a target pattern 110 having the trenches T.

Thereafter, the method may further include performing the processes described with reference to FIG. 2F to form trench patterns 170 in the trenches T and form a capping layer 180.

According to embodiments of the present disclosure, a method of forming a semiconductor device includes forming a nano-crystalline graphite carbon layer having a low stress and modifying the nano-crystalline graphite carbon layer to form an amorphous carbon layer having improved etching resistance. The amorphous carbon layer can be used as a mask pattern with excellent etching selectivity in an etching process.

According to embodiments of the present disclosure, wafer distortion and wiggling of a material layer can be suppressed.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A method of manufacturing a semiconductor device, the method comprising:
forming a target layer,
forming a pre-modification carbon layer over the target layer,
modifying and patterning the pre-modification carbon layer to form a post-modification carbon mask pattern by performing a modification process and a patterning process, and
forming trenches in the target layer by performing an etching process using the post-modification carbon mask pattern as an etching mask.

2. The method of claim 1,
wherein the pre-modification carbon layer includes sp2 hybrid carbon bonding structures and sp3 hybrid carbon bonding structures, and
in the pre-modification carbon layer, a number of the sp2 hybrid carbon bonding structures is greater than a number of the sp3 hybrid carbon bonding structures.

3. The method of claim 2,
wherein the sp2 hybrid carbon bonding structures are equal to or greater than 75% in the pre-modification carbon layer.

4. The method of claim 2,
wherein the sp3 hybrid carbon bonding structures are equal to or less than 20% in the pre-modification carbon layer.

5. The method of claim 2,
wherein the post-modification carbon mask pattern includes the sp2 hybrid carbon bonding structures and the sp3 hybrid carbon bonding structures,
wherein a number of the sp2 hybrid carbon bonding structures in the post-modification carbon mask pattern is less than the number of the sp2 hybrid carbon bonding structures in the pre-modification carbon layer, and
wherein a number of the sp3 hybrid carbon bonding structures in the post-modification carbon mask pattern is greater than the number of the sp2 hybrid carbon bonding structures in the pre-modification carbon layer.

6. The method of claim 5,
wherein the sp2 hybrid carbon bonding structures are equal to or greater than 40% and equal to or less than 75% in the post-modification carbon mask pattern, and
wherein the sp3 hybrid carbon bonding structures are equal to or greater than 25% and equal to or less than 60% in the post-modification carbon mask pattern.

7. The method of claim 1,
wherein the modification process includes performing an ion implantation process, and
wherein the ion implantation process includes implanting at least one of boron ions, boron compounds such as boron fluoride, carbon ions, silicon ions, silicon compound ions, argon ions, xenon ions, phosphorus ions, arsenic ions, germanium ions, indium ions, or antimony ions into the pre-modification carbon layer.

8. The method of claim 1, further comprising:
forming a buffer layer between the target layer and the pre-modification carbon layer,
wherein the buffer layer has an etch selectivity with respect to the post-modification carbon layer and the target layer.

9. The method of claim 8,
wherein the buffer layer includes at least one of a silicon nitride layer, a silicon boron nitride layer, a silicon carbon nitride layer, a silicon carbon layer, or an insulating layer that is denser than the etching target layer.

10. The method of claim 1, further comprising:
forming a gate dielectric layer over inner walls of the trenches, and
forming a gate electrode over the gate dielectric layer to fill the trenches.

11. The method of claim 1, further comprising:
forming barrier layers over the inner walls of the trenches, and forming plugs over the barrier layers to fill the trenches.

12. A method of manufacturing a semiconductor device, the method comprising:
forming a target layer,
forming a pre-modification carbon layer over the target layer,
patterning the pre-modification carbon layer to form a post-modification carbon mask pattern,
modifying the pre-modification carbon mask pattern to form a post-modification carbon mask pattern by performing an ion implantation process,
forming trenches in the target layer by performing an etching process using the post-modification carbon mask pattern as an etching mask, and
forming trench patterns in the trenches,
wherein each of the pre-modification carbon mask patterns and the post-modification carbon mask pattern includes sp2 hybrid carbon bonding structures and sp3 hybrid carbon bonding structures,
wherein a number of the sp3 hybrid carbon bonding structures in the pre-modification carbon mask pattern is less than a number of the sp3 hybrid carbon bonding structures in the post-modification carbon mask pattern.

13. The method of claim 12,
wherein a number of the sp2 hybrid carbon bonding structures in the pre-modification carbon mask pattern is greater than a number of the sp2 hybrid carbon bonding structures in the post-modification carbon mask pattern.

14. The method of claim 12,
wherein the sp2 hybrid carbon bonding structures are equal to or greater than 75% in the pre-modification carbon mask pattern, and
wherein the sp2 hybrid carbon bonding structures are equal to or less than 60% in the post-modification carbon mask pattern.

15. The method of claim 14,
wherein the sp3 hybrid carbon bonding structures are equal to or less than 20% in the pre-modification carbon mask pattern, and
wherein the sp3 hybrid carbon bonding structures are equal to or greater than 40% in the post-modification carbon mask pattern.

16. The method of claim 15,
wherein the sp2 hybrid carbon bonding structures are equal to or greater than 40% and equal to or less than 75% in the post-modification carbon layer, and
wherein the sp3 hybrid carbon bonding structures are equal to or greater than 25% and equal to or less than 60% in the post-modification carbon layer.

17. The method of claim 12,
wherein the modification process includes performing an ion implantation process, and
wherein the ion implantation process includes implanting at least one of boron ions, boron compounds such as boron fluoride, carbon ions, silicon ions, silicon compound ions, argon ions, xenon ions, phosphorus ions, arsenic ions, germanium ions, indium ions, or antimony ions into the pre-modification carbon layer.

18. A method of manufacturing a semiconductor device, the method comprising:
forming a pre-modification carbon layer over a target layer, and
modifying the pre-modification carbon layer to form a post-modification carbon layer by performing an ion implantation process,
wherein each of the pre-modification carbon layer and the post-modification carbon layer includes sp2 hybrid carbon bonding structures and sp3 hybrid carbon bonding structures,
wherein a number of the sp2 hybrid carbon bonding structures in the pre-modification carbon layer is greater than a number of the sp2 hybrid carbon bonding structures in the post-modification carbon layer, and
wherein a number of the sp3 hybrid carbon bonding structures in the pre-modification carbon layer is less than a number of the sp3 hybrid carbon bonding structures in the post-modification carbon layer.

19. The method of claim 18,
wherein the ion implantation process includes implanting at least one of boron ions, boron compounds, boron fluoride, carbon ions, silicon ions, silicon compound ions, argon ions, xenon ions, phosphorus ions, arsenic ions, germanium ions, indium ions, and antimony ions into the pre-modification carbon layer.

20. The method of claim 18,
wherein the sp2 hybrid carbon bonding structures are equal to or greater than 40% and equal to or less than 75% in the post-modification carbon layer, and
wherein the sp3 hybrid carbon bonding structures are equal to or greater than 25% and equal to or greater than 60% in the post-modification carbon layer.
